(19) United States
(12) Patent Application Publication
(10) Pub. No.: US 2026/0006844 A1
(43) Pub. Date: Jan. 1, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: I-Hsiang MA, Hsinchu (TW); Li-Wei YIN, Hsinchu (TW); Kai-Min CHIEN, New Taipei (TW); Min-Chia LEE, Hsinchu (TW); Kuo-Chin LIU, Hualien (TW); Yih-Ann LIN, Hsinchu (TW); Ryan Chia-Jen CHEN, Hsinchu (TW)

(21) Appl. No.: 18/907,655

(22) Filed: Oct. 7, 2024

Related U.S. Application Data
(60) Provisional application No. 63/664,763, filed on Jun. 27, 2024.

(51) Int. Cl. H01L 29/423; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017

(57) ABSTRACT

Embodiments of the present disclosure provide a semiconductor device structure and methods of forming the same. The structure includes a first semiconductor layer disposed over a substrate, a source/drain region disposed adjacent the first semiconductor layer, a gate spacer disposed over the first semiconductor layer, a native oxide layer disposed between the gate spacer and the source/drain region and between the gate spacer and the first semiconductor layer, a gate dielectric layer disposed between the native oxide layer and the first semiconductor layer, and a gate electrode layer disposed on the gate dielectric layer. The gate electrode layer includes a first portion having a first width and a second portion having a second width greater than the first width.

### CROSS-REFERENCE TO RELATED APPLICATIONS

This application claims priority to U.S. Provisional Application Ser. No. 63/664,763 filed Jun. 27, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, 1D, 1E, 1F, 1G, 1H, 1I, and 1J are perspective views of various stages of manufacturing a semiconductor device structure, in accordance with some embodiments.

FIGS. 2A, 2B, 2C, 2D, and 2E are cross-sectional side views of a portion of the semiconductor device structure shown in FIG. 1J during various stages of manufacturing, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

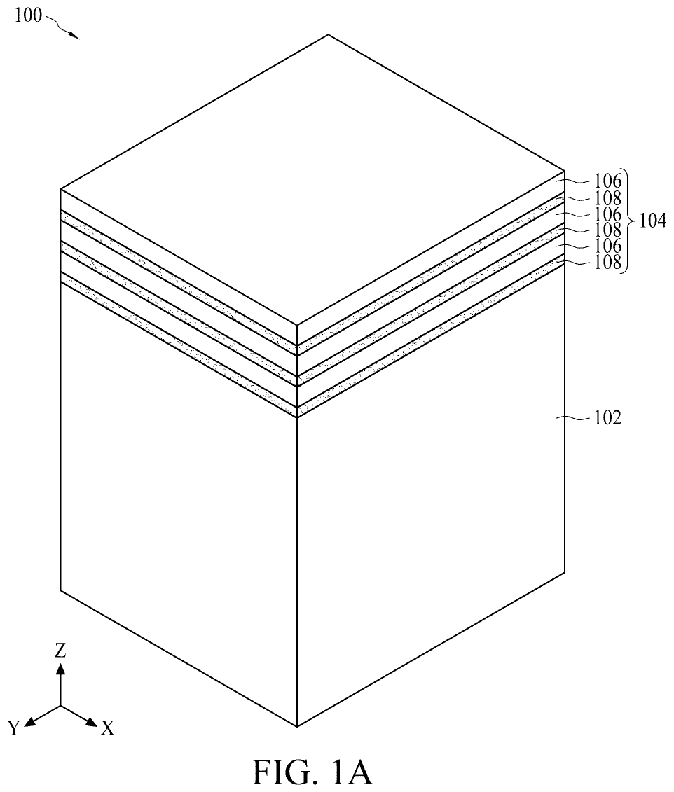

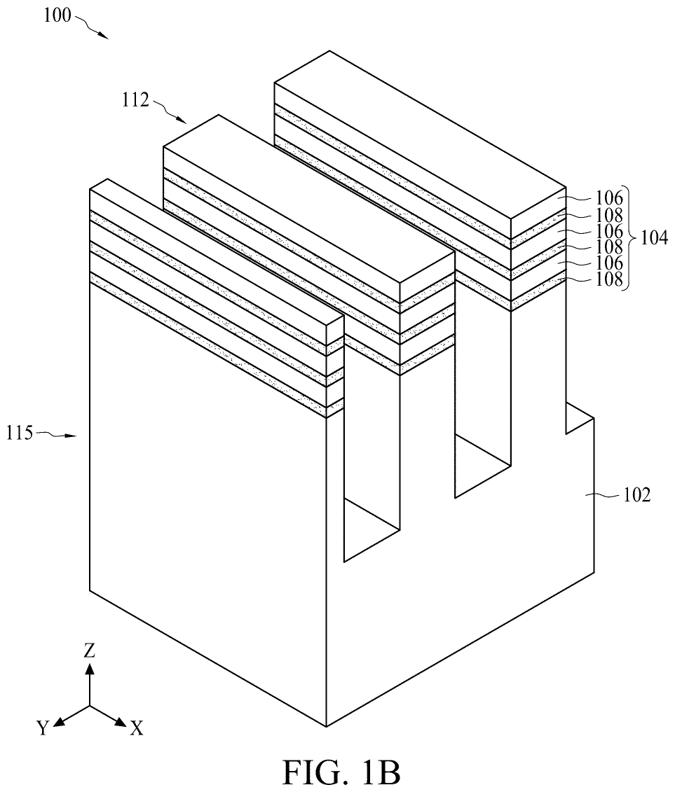

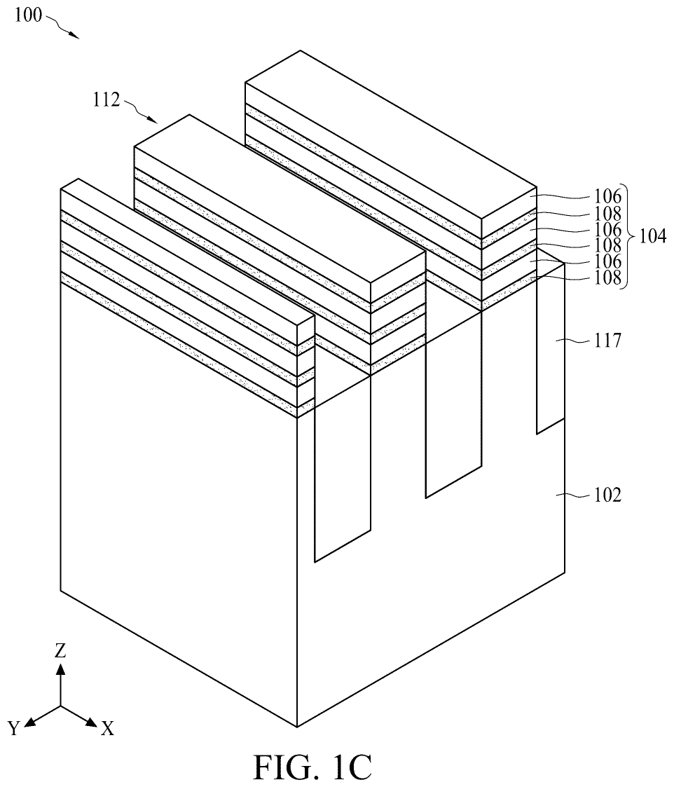

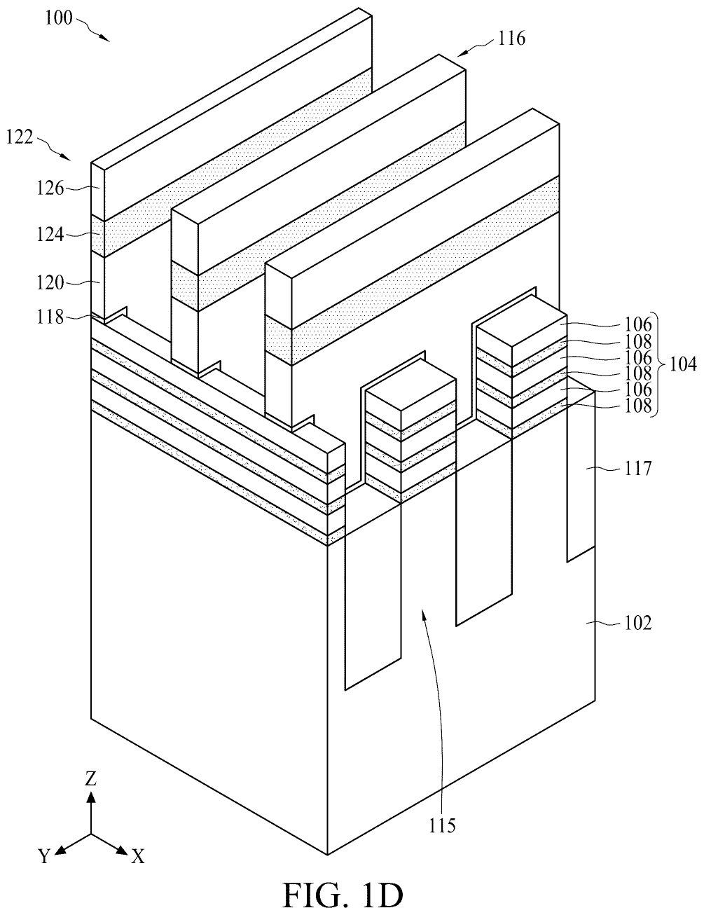

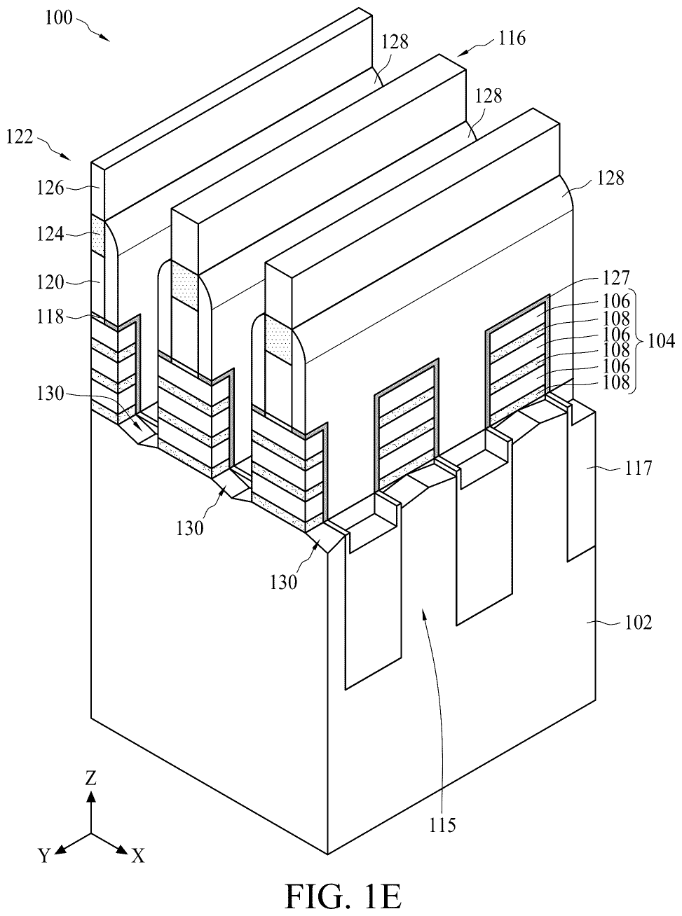

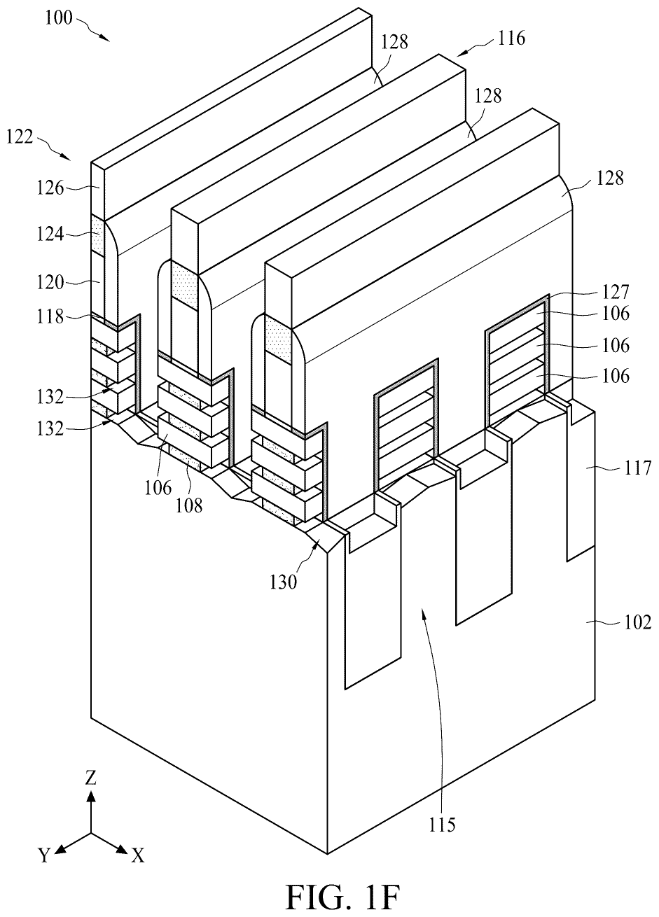

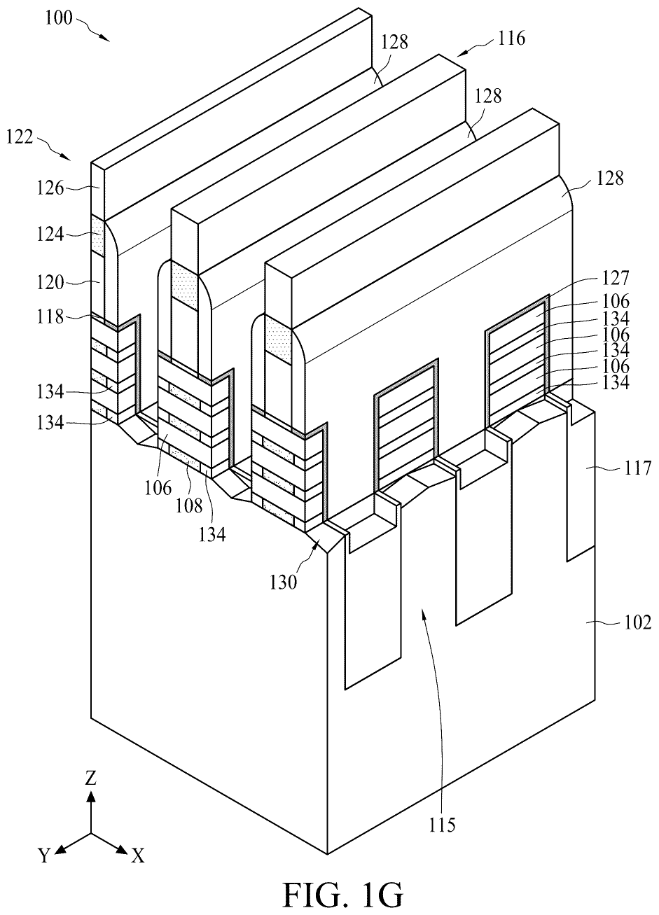

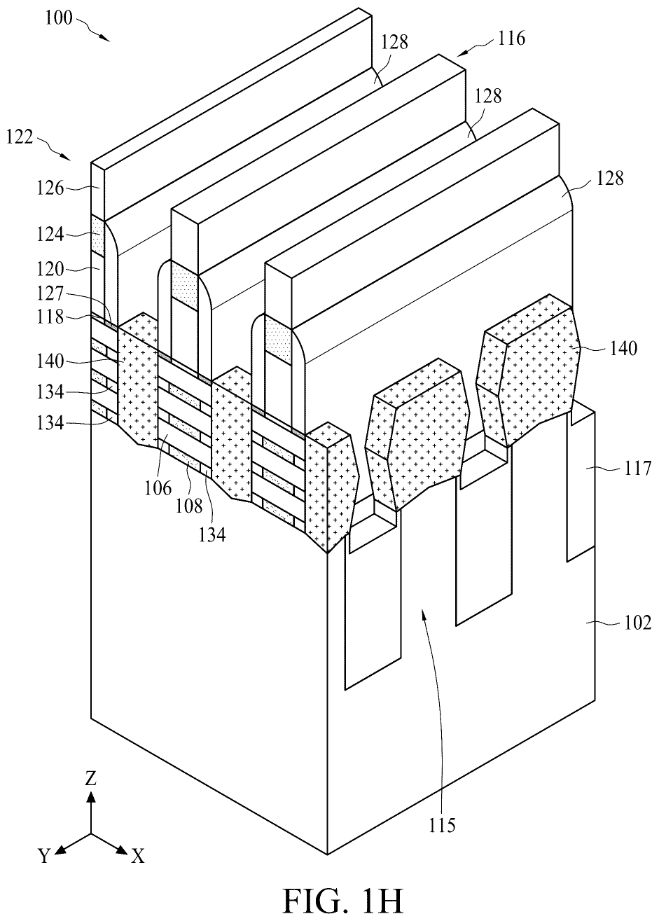

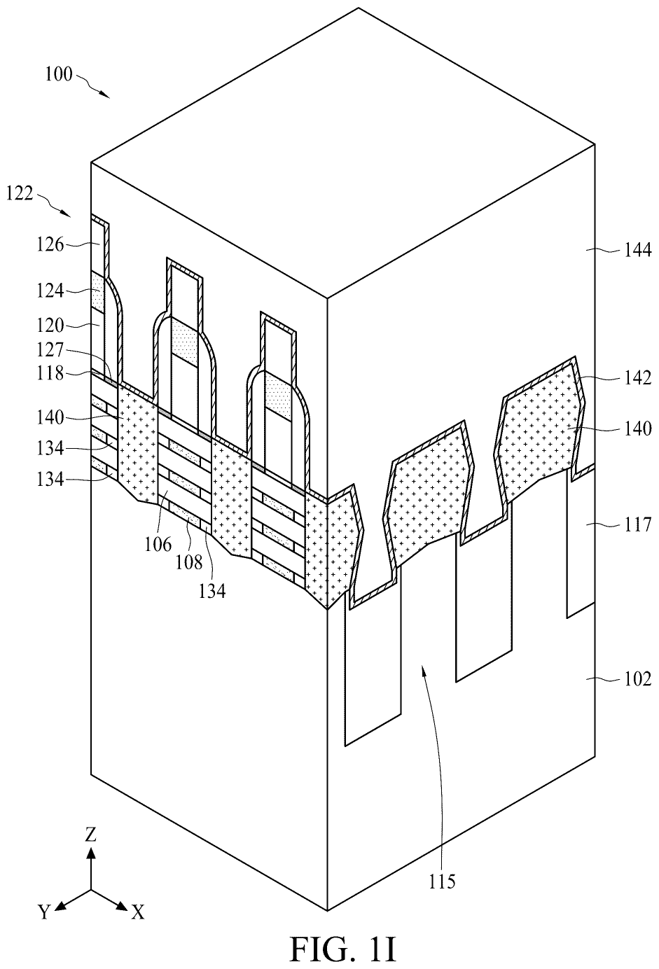

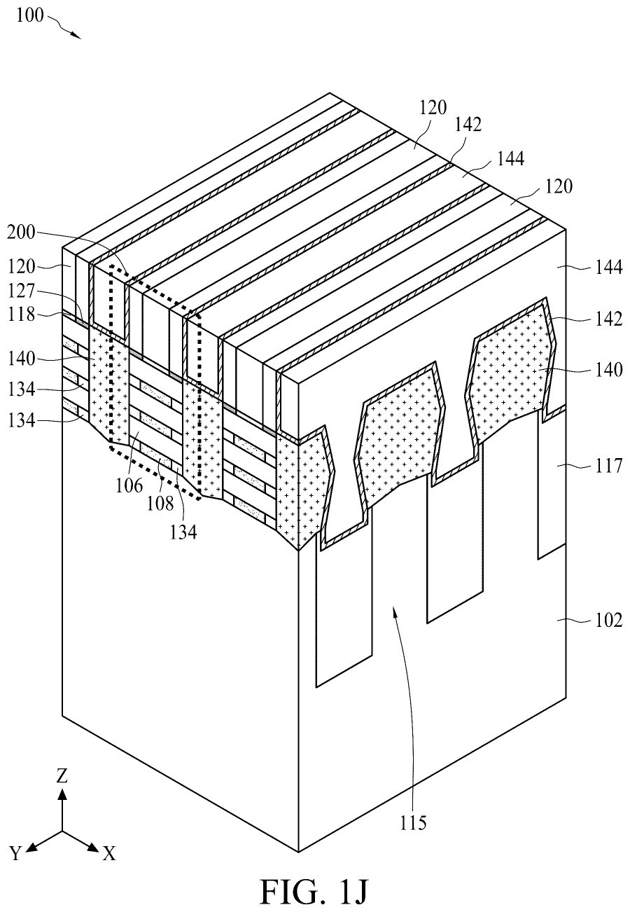

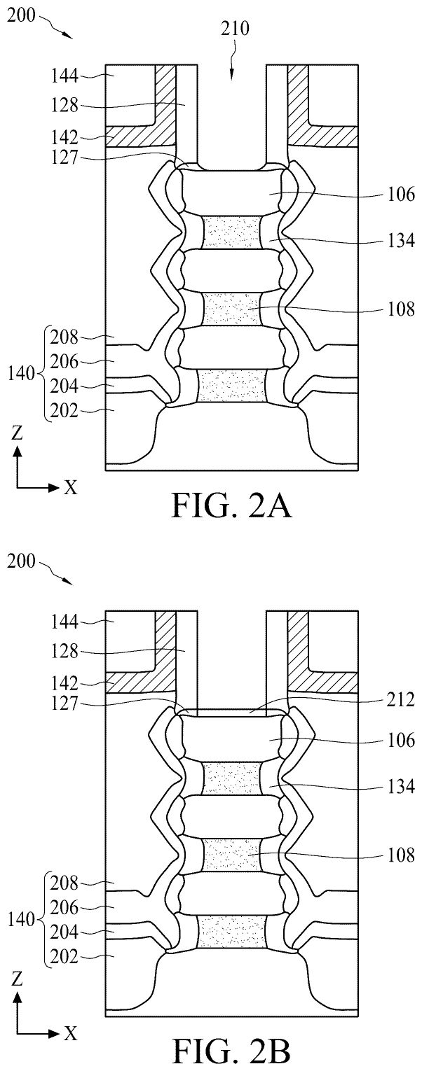

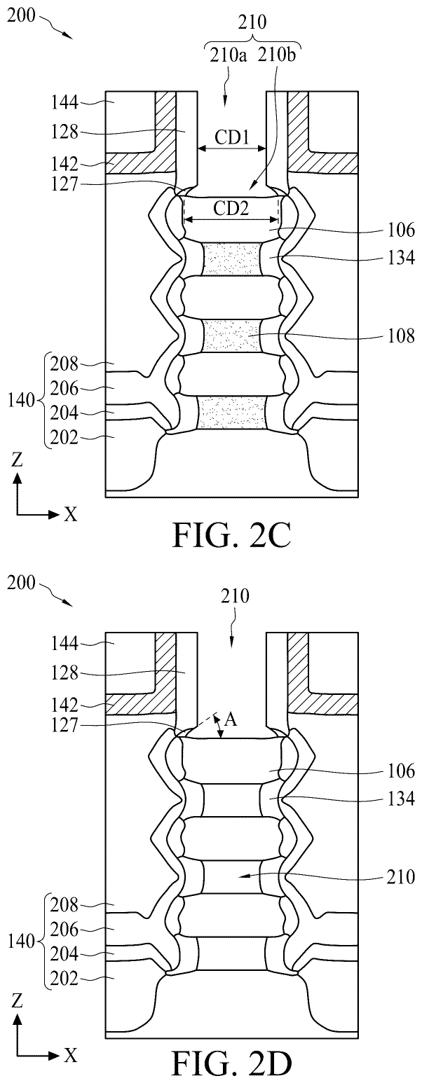

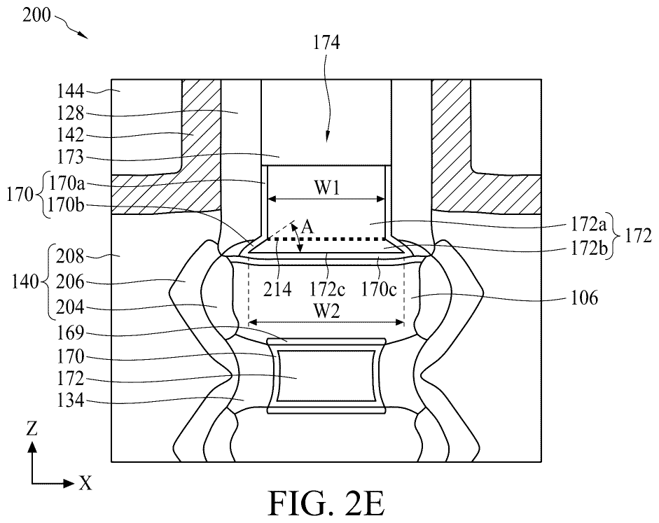

FIGS. 1-2E show exemplary processes for manufacturing a semiconductor device structure 100 according to embodiments of the present disclosure. It is understood that additional operations can be provided before, during, and after processes shown by FIGS. 1-2E, and some of the operations described below can be replaced or eliminated, for additional embodiments of the method. The order of the operations/processes is not limiting and may be interchangeable.

FIGS. 1A, 1B, 1C, 1D, 1E, 1F, 1G, 1H, 1I, and 1J are perspective views of various stages of manufacturing a semiconductor device structure 100, in accordance with some embodiments. As shown in FIG. 1A, a semiconductor device structure 100 includes a stack of semiconductor layers 104 formed over a front side of a substrate 102. The substrate 102 may be a semiconductor substrate. The substrate 102 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 102 is a silicon-on-insulator (SOI) substrate having an insulating layer (not shown) disposed between two silicon layers for enhancement. In one aspect, the insulating layer is an oxygen-containing layer.

The substrate 102 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GalnP, GalnAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. In some embodiments, the number of first semiconductor layers 106 ranges from two to 10.

In FIG. 1B, fin structures 112 are formed from the stack of semiconductor layers 104. Each fin structure 112 has an upper portion including the semiconductor layers 106, 108 and a substrate portion 115 formed from the substrate 102. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches in unprotected regions through the hard mask layer, through the stack of semiconductor layers 104, and into the substrate 102, thereby leaving the plurality of extending fin structures 112. The trenches extend along the X direction. The trenches may be etched using a dry etch (e.g., RIE), a wet etch, and/or combination thereof.

In FIG. 1C, after the fin structures 112 are formed, an insulating material 117 is formed on the substrate 102. The insulating material 117 initially fills the trenches between neighboring fin structures 112 until the fin structures 112 are embedded in the insulating material 117. Then, a planarization operation, such as a chemical mechanical polishing (CMP) method and/or an etch-back method, is performed such that the top of the fin structures 112 is exposed. Next, the insulating material 117 is recessed to form isolation regions. In some embodiments, the isolation regions are shallow trench isolation (STI) regions. The recess of the insulating material 117 exposes portions of the fin structures 112, such as the stack of semiconductor layers 104. The recess of the insulating material 117 reveals the trenches between the neighboring fin structures 112. The isolation regions may be formed using a suitable process, such as a dry etching process, a wet etching process, or a combination thereof. A top surface of the insulating material 117 may be level with or below a surface of the second semiconductor layers 108 in contact with the substrate portion 115 formed from the substrate 102.

The insulating material 117 may be made of silicon oxide, silicon nitride, silicon oxynitride (SiON), SiOCN, SiCN, fluorine-doped silicate glass (FSG), a low-K dielectric material, or any suitable dielectric material. The insulating material 117 may be formed by any suitable method, such as low-pressure chemical vapor deposition (LPCVD), plasma enhanced CVD (PECVD) or flowable CVD (FCVD).

In FIG. 1D, one or more sacrificial gate structures 116 are formed over the semiconductor device structure 100. The sacrificial gate structures 116 are formed over a portion of the fin structures 112. Each sacrificial gate structure 116 may include a sacrificial gate dielectric layer 118, a sacrificial gate electrode layer 120, and a mask layer 122. The sacrificial gate dielectric layer 118, the sacrificial gate electrode layer 120, and the mask layer 122 may be formed by sequentially depositing blanket layers of the sacrificial gate dielectric layer 118, the sacrificial gate electrode layer 120, and the mask layer 122, and then patterning those layers into the sacrificial gate structures 116. The sacrificial gate dielectric layer 118 may include one or more layers of dielectric material, such as a silicon oxide-based material. The sacrificial gate electrode layer 120 may include silicon such as polycrystalline silicon or amorphous silicon. The mask layer 122 may include more than one layer, such as an oxide layer 124 and a nitride layer 126. The portions of the fin structures 112 that are covered by the sacrificial gate electrode layer 120 of the sacrificial gate structure 130 serve as channel regions for the semiconductor device structure 100.

In FIG. 1E, in some embodiments, a native oxide layer 127 is formed on the exposed portions of the fin structures 112. The native oxide layer 127 may be formed as a result of oxidation of the first and second semiconductor layers 106, 108. The oxidation may occur when the semiconductor device structure 100 is exposed to air during the transferring of the semiconductor device structure 100 from one processing chamber or tool to another processing chamber or tool. Next, gate spacers 128 are formed on sidewalls of the sacrificial gate structures 116 and on the native oxide layer 127. The gate spacers 128 may be formed by conformally depositing one or more layers and anisotropically etching the one or more layers, for example. In some embodiments, the gate spacers 128 are also formed on sidewalls of the exposed portions of the fin structures 112. The gate spacer 128 may be made of a dielectric material such as silicon oxide, silicon nitride, silicon carbide, silicon oxynitride, SiCN, silicon oxycarbide, SiOCN, and/or combinations thereof.

Next, the portions of the fin structures 112 not covered by the sacrificial gate structure 116 and the gate spacers 128 are recessed to a level above, at, or below the top surfaces of the insulating material 117, as shown in FIG. 1E. In some embodiments, the fin structures 112 are recessed to a level below the top surface of the insulating material 117. The recess of the portions of the fin structures 112 can be done by an etch process, either isotropic or anisotropic etch process, and the etch process may be selective with respect to the first and second semiconductor layers 106, 108. The etch process may be a dry etch, such as a RIE, NBE, or the like, or a wet etch, such as using tetramethyalammonium hydroxide (TMAH), ammonium hydroxide (NH₄OH), or any suitable etchant. In some embodiments, the insulating material 117 may be recessed by the etch process.

In FIG. 1F, edge portions of each second semiconductor layer 108 of the stack of semiconductor layers 104 are removed horizontally along the X direction. The removal of the edge portions of the second semiconductor layers 108 forms cavities 132, as shown in FIG. 1F. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities 132 to form dielectric spacers 134. The dielectric spacers 134 may be made of a low-K dielectric material, such as SiON, SiCN, SiOC, SiOCN, or SiN. The dielectric spacers 134 may be formed by first forming a conformal dielectric layer using a conformal deposition process, such as ALD, followed by an anisotropic etching to remove portions of the conformal dielectric layer other than the dielectric spacers 134. The dielectric spacers 134 are protected by the first semiconductor layers 106 during the anisotropic etching process. The remaining second semiconductor layers 108 are capped between the dielectric spacers 134 along the X direction.

In FIG. 1H, source/drain (S/D) regions 140 are formed from the first semiconductor layers 106. The S/D regions 140 may grow both vertically and horizontally to form facets, which may correspond to crystalline planes of the material used for the first semiconductor layer 106. In this disclosure, a source region and a drain region are interchangeably used, and the structures thereof are substantially the same. Furthermore, source/drain region(s) may refer to a source or a drain, individually or collectively dependent upon the context. The S/D regions 140 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 140. The S/D regions 140 may be formed by an epitaxial growth method using CVD, ALD or MBE.

In some embodiments, the S/D region 140 includes a first semiconductor material 202, a second semiconductor material 204, a third semiconductor material 206, and a fourth semiconductor material 208, as shown in FIG. 2A. In some embodiments, the first semiconductor material 202 includes undoped silicon or undoped SiGe. The first semiconductor material 202 may be first formed on semiconductor surfaces, such as on the exposed substrate portions 115 and on the first semiconductor layers 106, by epitaxy. A subsequent etch process is performed to remove the portions of the semiconductor material 202 formed on the first semiconductor layers 106. The second semiconductor material 204 may be formed on the first semiconductor material 202 and the first semiconductor layer 106, as shown in FIG. 2A. The second semiconductor material 204 may include doped Si or doped SiGe and may have a first dopant concentration. The third semiconductor material 206 may be formed on the second semiconductor material 204. The third semiconductor material 206 may include doped Si or doped SiGe and may have a second dopant concentration. The fourth semiconductor material 208 may be formed on the third semiconductor material 206. The fourth semiconductor material 208 may include doped Si or doped SiGe and may have a third dopant concentration. In some embodiments, the third dopant concentration is greater than the second dopant concentration, which is greater than the first dopant concentration.

In FIG. 1I, a contact etch stop layer (CESL) 142 is conformally formed on the exposed surfaces of the semiconductor device structure 100. The CESL 142 covers the sidewalls of the sacrificial gate structure 116, the insulating material 117, and the S/D regions 140. The CESL 142 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 144 is formed on the CESL 142 over the semiconductor device structure 100. The materials for the ILD layer 144 may include compounds including Si, O, C, and/or H, such as silicon oxide, SiCOH, or SiOC. Organic materials, such as polymers, may also be used for the ILD layer 144. The ILD layer 144 may be deposited by a PECVD process or other suitable deposition technique. In some embodiments, after formation of the ILD layer 144, the semiconductor device structure 100 may be subject to a thermal process to anneal the ILD layer 144.

After the ILD layer 144 is formed, a planarization operation, such as CMP, is performed on the semiconductor device structure 100 until the sacrificial gate electrode layer 120 is exposed, as shown in FIG. 1J.

FIGS. 2A, 2B, 2C, 2D, and 2E are cross-sectional side views of a portion 200 of the semiconductor device structure 100 shown in FIG. 1J during various stages of manufacturing, in accordance with some embodiments. As shown in FIG. 2A, the S/D region 140 includes the first semiconductor material 202, the second semiconductor material 204, the third semiconductor material 206, and the fourth semiconductor material 208. After the CMP process to expose the sacrificial gate electrode layer 120, the sacrificial gate electrode layer 120 and the sacrificial gate dielectric layer 118 are removed, as shown in FIG. 2A. An opening 210 is formed between the gate spacers 128 after the removal of the sacrificial gate electrode layer 120 and the sacrificial gate dielectric layer 118. The ILD layer 144 protects the S/D regions 140 during the removal processes. In some embodiments, the sacrificial gate electrode layer 120 may be first removed by any suitable process, such as dry etch, wet etch, or a combination thereof, followed by the removal of the sacrificial gate dielectric layer 118, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 120 but not the gate spacers 128, the ILD layer 144, the CESL 142, and the sacrificial gate dielectric layer 118. Then, the sacrificial gate dielectric layer 118 is removed by an etch process. In some embodiments, the etch process to remove the sacrificial gate dielectric layer 118 is a chemical etch process without the presence of plasma. For example, the chemical etch process is an isotropic etch process that uses HF and NH₃ as etchants. The chemical etch process may be performed at a processing pressure ranging from about 500 mTorr to about 1000 mTorr and at a processing temperature ranging from about 40 degrees Celsius to about 80 degrees Celsius. The chemical etch process to remove the sacrificial gate dielectric layer 118 does not substantially affect the native oxide layer 127. If the native oxide layer 127 is removed, the risk of electrical short between the subsequently formed gate electrode layer 172 (FIG. 2E) and the S/D region 140 may be increased.

After the removal of the sacrificial gate electrode layer 120 and the sacrificial gate dielectric layer 118, the semiconductor device structure 100 is transferred to another chamber or tool for subsequent processing. As a result, another native oxide layer 212 is formed on the exposed surface of the first semiconductor layer 106, as shown in FIG. 2B. In some embodiments, the thickness of the native oxide layer 212 is less than a thickness of the native oxide layer 127. Thus, if the native oxide layer 127 is removed during the removal of the sacrificial gate dielectric layer 118, the native oxide layer 212 is not thick enough to provide isolation between the gate electrode layer 172 and the S/D region 140. In some embodiments, the thickness of the native oxide layer 212 is greater than or equal to the thickness of the native oxide layer 127.

In FIG. 2C, an etch process is performed to remove the native oxide layer 212 and portions of the native oxide layer 127. In some embodiments, the etch process is a low temperature chemical etch process without the presence of plasma. The chemical etch process may be performed at a processing temperature less than that of the chemical etch process to remove the sacrificial gate dielectric layer 118. With the lower processing temperature, more reactive species may be adsorbed on the portions of the native oxide layer 127 located in the corners. As a result, the opening 210 includes a first portion 210a having a first critical dimension CD1 and a second portion 210b having a second critical dimension CD2. In some embodiments, the first critical dimension CD1 is substantially constant, and the second critical dimension CD2 varies. For example, the second critical dimension CD2 increases in a direction towards the first semiconductor layer 106. In some embodiments, the second critical dimension CD2 is the smallest at the interface between the first portion 210a and the second portion 210b of the opening 210, and the second critical dimension CD2 is the largest at the interface between the second portion 210b of the opening 210 and the topmost first semiconductor layer 106. In some embodiments, the largest second critical dimension CD2 is about two percent to about 20 percent greater than the first critical dimension CD1, such as from about 10 percent to about 15 percent greater than the first critical dimension CD1.

With the larger critical dimension CD2, more space is available for the subsequently deposited gate electrode layer 172. In other words, the subsequently deposited gate electrode layer 172 has increased dimensions as a result of the larger critical dimension CD2. As a result, wafer acceptable test (WAT) performance is improved.

In some embodiments, an angle A is formed between the exposed surface of the native oxide layer 127 and the top surface of the topmost first semiconductor layer 106, as shown in FIG. 2D. The angle A may be an acute angle. In some embodiments, the angle A ranges from about 60 degrees to about 85 degrees. The acute angle A is a result of the low temperature chemical etch process described in FIG. 2C. The low temperature chemical etch process may utilize etchants such as HF and NH₃. In some embodiments, the flow rate of HF gas ranges from about 8 standard cubic centimeters (sccm) to about 50 sccm, and the flow rate of NH₃ gas ranges from about 20 sccm to about 100 sccm. The processing temperature of the low temperature chemical etch process is less than that of the chemical etch process to remove the sacrificial gate dielectric layer 118. In some embodiments, the processing temperature of the low temperature chemical etch process ranges from about 20 degrees Celsius to about 30 degrees Celsius. In some embodiments, the processing pressure of the low temperature chemical etch process is less than that of the chemical etch process to remove the sacrificial gate dielectric layer 118. In some embodiments, the processing pressure of the low temperature chemical etch process ranges from about 150 m Torr to about 450 mTorr.

As shown in FIG. 2C, the remaining native oxide layer 127 covers the S/D regions 140. In some embodiments, the second semiconductor material 204 formed on the sidewall of the topmost first semiconductor layer 106 is covered by the remaining native oxide layer 127. In some embodiments, the remaining native oxide layer 127 is located between and in contact with the gate spacer 128 and the S/D region 140, as shown in FIG. 2C. The low temperature chemical etch process is performed for a time duration to ensure the remaining native oxide layer 127 covers the S/D regions 140. If a portion of the S/D region 140 is exposed to the opening 210, electrical short between the S/D region 140 and the subsequently deposited gate electrode layer 172 may occur. In some embodiments, the time duration of the low temperature chemical etch process is less than or equal to about 5 seconds, such as from about 2 seconds to about 5 seconds. If the time duration is less than about 2 seconds, the portions of the native oxide layer 127 may not be removed, and the available space for the gate electrode layer 172 is reduced. On the other hand, if the time duration is greater than about 5 seconds, the S/D regions 140 may be exposed. As a result of the low temperature chemical etch process, the space available for the gate electrode layer 172 is enlarged, and the S/D regions 140 are not exposed.

In FIG. 2D, the second semiconductor layers 108 are removed after the native oxide layer 212 and the portions of the native oxide layer 127 are removed. The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the gate spacers 128, the dielectric spacers 134, and the native oxide layer 127. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

In FIG. 2E, after the formation of the nanostructure channels (i.e., the exposed portions of the first semiconductor layers 106), an interfacial layer (IL) 169 is formed to surround the exposed portions of the first semiconductor layers 106 and the substrate portion 115, and a gate dielectric layer 170 is formed on the IL 169. In some embodiments, the IL 169 is selectively formed on the semiconductor materials of the first semiconductor layers 106 and the substrate portion 115, and the gate dielectric layer 170 is also formed on the insulating material 117 and the gate spacers 128. In some embodiments, the IL 169 is an oxide layer, such as silicon oxide. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTIO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. In some embodiments, as shown in FIG. 2E, the IL 169 is in contact with the native oxide layer 127.

Next, the gate electrode layer 172 is formed on the gate dielectric layer 170, as shown in FIG. 2E. The gate electrode layer 172 may include one or more work function layers and a bulk metal fill. The materials for the work function layers may be chosen based upon the type of device to be formed. Exemplary p-type work function materials may include Al, TiAlC, TiN, TaN, Ru, Mo, WN, ZrSi₂, MoSi₂, TaSi₂, NiSi₂, other suitable p-type work function materials, or combinations thereof. Exemplary n-type work function materials may include Ti, Ag, TaAl, TaAlC, TiAIN, TaC, TaCN, TaSiN, Mn, Zr, other suitable n-type work function materials, or combinations thereof. The one or more work function layers may be deposited by CVD, PVD, ALD, and/or other suitable process. In some embodiments, the one or more work function layers are conformal layers. The bulk metal fill may be deposited on the one or more work function layers, and the bulk metal fill may be made of W, Cu, Ru, Co, or other suitable material. In some embodiments, the one or more work function layers have “U” shaped cross sections, and the bottom and sidewalls of the bulk metal fill are surrounded by the one or more work function layers. The gate dielectric layer 170 and the gate electrode layer 172 together may be referred to as a gate structure 174.

In some embodiments, as shown in FIG. 2E, the gate electrode layer 172 disposed over the topmost first semiconductor layer 106 includes a first portion 172a and a second portion 172b. The first portion 172a is disposed above the second portion 172b, and the first portion 172a and the second portion 172b are defined by an imaginary line 214, as shown in FIG. 2E. In some embodiments, the first portion 172a has a first width W1 along the X direction, and the second portion 172b has a second width W2 along the X direction. Similar to the first and second critical dimensions CD1, CD2, the first width W1 may be constant, and the second width W2 may vary. In some embodiments, the second width W2 increases in a direction towards the first semiconductor layer 106. In some embodiments, the second width W2 is the smallest at the imagine line 214 between the first portion 172a and the second portion 172b, and the second width W2 is the largest at the interface between the second portion 172b of the gate electrode layer 172 and a bottom portion of the gate dielectric layer 170. In some embodiments, the largest second width W2 is about two percent to about 20 percent greater than the first width W1, such as from about 10 percent to about 15 percent greater than the first width W1.

In some embodiments, the first portion 172a of the gate electrode layer 172 has a rectangular cross section, and the second portion 172b of the gate electrode layer has a trapezoidal cross section, as shown in FIG. 2E. The sidewalls of the first portion 172a are substantially parallel to each other, and the sidewalls of the second portion 172b are not parallel to each other. In some embodiments, the sidewall of the second portion 172b and a bottom surface 172c of the gate electrode layer 172 form the angle A, which may range from about 60 degrees to about 85 degrees. The larger width W2 and the trapezoidal cross section of the second portion 172b mean more gate electrode layer 172 is deposited in the corners compared to conventional gate electrode layers. As a result, transistor electrical performance and WAT performance may be improved.

The gate dielectric layer 170 disposed over the topmost first semiconductor layer 106 includes a first portion 170a disposed on opposite sidewalls of the first portion 172a of the gate electrode layer 172, a second portion 170b disposed on opposite sidewalls of the second portion 172b of the gate electrode layer 172, and a third portion 170c in contact with the bottom surface 172c of the gate electrode layer 172. In some embodiments, the second portion 170b of the gate dielectric layer 170 and the third portion 170c of the gate dielectric layer 170 form the angle A, which may range from about 60 degrees to about 85 degrees.

As described above, the gate electrode layer 172 may include one or more work function layers and a bulk metal fill. In some embodiments, the one or more work function layers are deposited in the opening 210 and on the ILD layer 144, and the bulk metal fill is deposited on the one or more work function layers in the opening 210 and over the ILD layer 144. Next, a planarization process, such as a CMP process, may be performed to remove the portions of the one or more work function layers and the bulk metal fill formed over the ILD layer 144. Then, a metal gate etch back (MGEB) process may be performed to recess the gate electrode layer 172 located between the gate spacers 128, and a cap layer 173 is deposited on the recessed gate electrode layer 172. In some embodiments, the cap layer 173 may be made of a metal, such as tungsten. In some embodiments, the cap layer 173 is made of fluorine free tungsten (FFW). In some embodiments, the MGEB process also recesses the gate dielectric layer 170 located between the gate spacers 138, and the cap layer 173 is deposited on the gate dielectric layer 170, as shown in FIG. 2E.

Embodiments of the present disclosure provide a semiconductor device structure 100. The semiconductor device structure 100 includes a gate electrode layer 172 having a first portion 172a and a second portion 172b. The first portion 172a has a first width W1 and the second portion 172b has a second width W2 substantially greater than the first width W1. Some embodiments may achieve advantages. For example, the larger second width W2 means more gate electrode layer 172 is deposited in the corners. As a result, transistor electrical performance and WAT performance may be improved.

An embodiment is a structure. The structure includes a first semiconductor layer disposed over a substrate, a source/drain region disposed adjacent the first semiconductor layer, a gate spacer disposed over the first semiconductor layer, a native oxide layer disposed between the gate spacer and the source/drain region and between the gate spacer and the first semiconductor layer, a gate dielectric layer disposed between the native oxide layer and the first semiconductor layer, and a gate electrode layer disposed on the gate dielectric layer. The gate electrode layer includes a first portion having a first width and a second portion having a second width greater than the first width.

Another embodiment is a structure. The structure includes a semiconductor layer disposed over a substrate, first and second gate spacers disposed over the semiconductor layer, and a gate electrode layer disposed over the semiconductor layer and between the first and second gate spacers. The gate electrode layer includes a first portion having a rectangular cross section and a second portion having a trapezoidal cross section, and a first sidewall of the second portion of the gate electrode layer and a bottom surface of the gate electrode layer form an angle. The angle ranges from 60 degrees to 85 degrees.

A further embodiment is a method. The method includes forming a fin structure from a substrate, depositing a sacrificial gate structure over a first portion of the fin structure, forming a native oxide layer on a second portion of the fin structure, and forming a gate spacer adjacent the sacrificial gate structure. The gate spacer is formed on the native oxide layer. The method further includes removing the sacrificial gate structure to form an opening and removing a portion of the native oxide layer. The opening has a first portion having a first critical dimension and a second portion having a second critical dimension greater than the first critical dimension. The method further includes forming a gate electrode layer in the opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first semiconductor layer disposed over a substrate;
a source/drain region disposed adjacent the first semiconductor layer;
a gate spacer disposed over the first semiconductor layer;
a native oxide layer disposed between the gate spacer and the source/drain region and between the gate spacer and the first semiconductor layer;
a gate dielectric layer disposed between the native oxide layer and the first semiconductor layer; and
a gate electrode layer disposed on the gate dielectric layer, wherein the gate electrode layer comprises a first portion having a first width and a second portion having a second width greater than the first width.

2. The semiconductor device structure of claim 1, wherein the native oxide layer is in contact with the gate spacer and the source/drain region.

3. The semiconductor device structure of claim 2, wherein the source/drain region comprises a semiconductor material in contact with the first semiconductor layer, wherein the native oxide layer is in contact with the semiconductor material.

4. The semiconductor device structure of claim 1, further comprising an interfacial layer disposed on and in contact with the first semiconductor layer.

5. The semiconductor device structure of claim 4, wherein the interfacial layer is in contact with the native oxide layer and the gate dielectric layer.

6. The semiconductor device structure of claim 1, wherein the second width is two percent to 20 percent greater than the first width.

7. The semiconductor device structure of claim 6, wherein the second width is 10 percent to 15 percent greater than the first width.

8. The semiconductor device structure of claim 1, further comprising a second semiconductor layer disposed below the first semiconductor layer, wherein the gate dielectric layer and the gate electrode layer are disposed between the first and second semiconductor layers.

9. A semiconductor device structure, comprising:
a semiconductor layer disposed over a substrate;
first and second gate spacers disposed over the semiconductor layer; and
a gate electrode layer disposed over the semiconductor layer and between the first and second gate spacers, wherein the gate electrode layer comprises a first portion having a rectangular cross section and a second portion having a trapezoidal cross section, a first sidewall of the second portion of the gate electrode layer and a bottom surface of the gate electrode layer form an angle, and the angle ranges from 60 degrees to 85 degrees.

10. The semiconductor device structure of claim 9, wherein the first portion of the gate electrode layer comprises second and third sidewalls, wherein the second and third sidewalls are parallel to each other.

11. The semiconductor device structure of claim 10, wherein the first sidewall of the second portion of the gate electrode layer is connected to the second sidewall of the first portion of the gate electrode layer.

12. The semiconductor device structure of claim 9, further comprising an interfacial layer disposed on and in contact with the semiconductor layer.

13. The semiconductor device structure of claim 12, further comprising a gate dielectric layer disposed on and in contact with the interfacial layer, wherein the gate electrode layer is disposed on and in contact with the gate dielectric layer.

14. The semiconductor device structure of claim 13, further comprising a native oxide layer disposed between and in contact with the first gate spacer and the gate dielectric layer.

15. The semiconductor device structure of claim 14, further comprising a source/drain region in contact with the semiconductor layer, wherein the native oxide layer is in contact with the source/drain region.

16. A method, comprising:
forming a fin structure from a substrate;
depositing a sacrificial gate structure over a first portion of the fin structure;
forming a native oxide layer on a second portion of the fin structure;
forming a gate spacer adjacent the sacrificial gate structure, wherein the gate spacer is formed on the native oxide layer;
removing the sacrificial gate structure to form an opening;
removing a portion of the native oxide layer, wherein the opening has a first portion having a first critical dimension and a second portion having a second critical dimension greater than the first critical dimension; and
forming a gate electrode layer in the opening.

17. The method of claim 16, wherein the portion of the native oxide layer is removed by a low temperature chemical etch process.

18. The method of claim 17, wherein a processing pressure of the low temperature chemical etch process ranges from about 150 mTorr to about 450 mTorr.

19. The method of claim 18, wherein a processing temperature of the low temperature chemical etch process ranges from about 20 degrees Celsius to about 30 degrees Celsius.

20. The method of claim 16, wherein the second critical dimension is about 10 percent to about 15 percent greater than the first critical dimension.
